(19) United States
(12) Patent Application Publication
(10) Pub. No.: US 2016/0276471 A1
(43) Pub. Date: Sep. 22, 2016

(54) Semiconductor Component and Method for Producing a Semiconductor Component in a Substrate having a Crystallographic (100) Orientation

(71) Applicant: ROBERT BOSCH GMBH, Stuttgart (DE)

(72) Inventor: Francisco Hernandez Guillen, Stuttgart (DE)

(21) Appl. No.: 15/033,497

(22) PCT Filed: Oct. 6, 2014
(86) PCT No.: PCT/EP2014/071333

§ 371 Date: Apr. 29, 2016

(30) Foreign Application Priority Data
Oct. 31, 2013 (DE) 10 2013 222 160.6

(51) Int. Cl. H01L 29/778; H01L 29/06; H01L 21/02; H01L 29/205; H01L 29/04

(52) U.S. Cl. CPC H01L 29/778; H01L 29/205; H01L 29/045; H01L 21/0254; H01L 21/02433; H01L 21/02381; H01L 29/0692

(57) ABSTRACT

A semiconductor component includes a substrate and a gallium nitride-containing first functional element which is implemented in the surface of the substrate. The substrate has a crystallographic (100) orientation.

The present invention relates to a semiconductor component comprising a substrate and a first functional element comprising gallium nitride, said first functional element being realized within the surface of the substrate, and to a method for producing a semiconductor component in a substrate having a crystallographic (100) orientation.

### Prior Art

In the prior art for some time now semiconductor components comprising gallium-nitride-based functional elements realized either on gallium nitride substrates in the context of so-called homoepitaxy or on a different substrate than gallium nitride, such as a silicon substrate, for example, in the context of so-called heteroepitaxy have already been providing a basis for sensors, radiofrequency components, light applications such as LEDs or power components.

In this case, heteroepitaxy-based semiconductor components are usually realized on silicon wafers having a (111)-oriented crystal structure. However, substrates having such crystal structures are not those preferred by the semiconductor industry for realizing silicon-based semiconductor components, particularly since substrates having (100)-oriented crystal planes or crystal structures are better suited to the implementation of CMOS processes or to the realization of CMOS components.

### Disclosure of the Invention

According to the invention, a semiconductor component is provided which comprises a substrate and a first functional element comprising gallium nitride, said first functional element being realized within the surface of the substrate. According to the invention, the substrate has a crystallographic (100) orientation.

The advantage of a semiconductor component embodied in this way resides in the possibility of realizing gallium-nitride-based functional elements in the context of a heteroepitaxy on a crystallographically (100)-oriented substrate. This crystallographic (100) orientation, preferred in particular for realizing CMOS components, thus enables the realization of functional elements comprising gallium nitride in and/or on a crystallographically (100)-oriented substrate that is better suited to realizing CMOS components and/or to carrying out CMOS processes.

Preferably, the substrate relative to the surface of the semiconductor component or the surface of the substrate itself in which the first functional element is realized has a crystallographic (100) orientation. To put it another way, the first functional element is thus preferably realized on and/or in (100)-oriented crystal planes.

In one preferred embodiment, the substrate is a silicon substrate. Silicon is the most frequently used substance in the semiconductor industry. Silicon is cost-effective and simple to process.

Preferably, the first functional element comprising gallium nitride is arranged at least partly within a structure arranged in the surface of the substrate. Such a structure makes it possible to implement the realization of the first functional element on and/or in the surface of the crystallographically (100)-oriented substrate in an advantageous manner since, by virtue of the structure, local crystal planes having an altered crystallographic orientation can be realized in and/or on the surface of the substrate, which crystal planes are better suited to a gallium nitride epitaxy.

Preferably, the structure is a cutout which forms a notch in the surface of the substrate, wherein at least one of the structure surfaces has a crystallographic (111) orientation. With further preference, at least one of the structure surfaces of the structure comprises a substantially crystallographically (111)-oriented structure surface. In such an exemplary embodiment, therefore, a structure having at least one crystallographically (111)-oriented structure surface preferred for realizing functional elements comprising gallium nitride is provided locally in the globally crystallographically (100)-oriented substrate. To put it another way, preferably at least one of the structure surfaces of the structure is formed by a (111)-oriented crystal plane. The surface of the substrate is thus suitable both for realizing CMOS components, for example, and for realizing components comprising gallium nitride.

Preferably, the structure has a V-shaped cross section and two structure surfaces angled with respect to one another and with respect to the surface of the substrate, which have in each case a crystallographic (111) orientation. To put it another way, the structure preferably has a V-shaped cross section and two structure surfaces angled with respect to one another and with respect to the surface of the substrate, which are formed in each case by a crystallographically (111)-oriented crystal plane. In such an exemplary embodiment, the first functional element comprising gallium nitride is realized completely on crystallographically (111))-oriented structure surfaces within the surface of the crystallographically (100)-oriented substrate. Consequently, the first functional element comprising gallium nitride is thus realized completely on a crystal structure preferred for the growth of gallium nitride. Besides the already mentioned advantage of the improved heterogeneous integration of, for example, silicon and gallium nitride or silicon and other III-V substance combinations, wherein III and V in each case denote at least one substance from a main group of the periodic table of the elements, a further advantage of such exemplary embodiments is that the surface area is enlarged overall by the described structures compared with a substrate surface without structures. Thus, if two wafers having identical dimensions are present, for example, then as a result of the arrangements of above structures on a first of said wafers it is possible to realize more components than on the second wafer, on which no structures as described above are provided.

In one preferred embodiment, at least one gallium nitride layer which forms a part of the first functional element is grown on the at least one structure surface. Such a gallium nitride layer can be fabricated with high quality and be used very well for realizing for example sensors, radiofrequency or high-power components, LEDs or other optoelectronic components.

Preferably, a layer for forming a heterostructure with the gallium nitride layer and/or an electrically conductive contact layer and/or at least one further layer are/is arranged within the structure, wherein the at least one further layer forms a dielectric spacer and/or a gate electrode of the semiconductor component. Furthermore preferably, the first functional element is a transistor. By way of example, during the production of a first functional element embodied as a transistor, by means of the deposition of a further layer functioning as a dielectric spacer, it is possible to define the distance between source and drain electrodes.

In one preferred embodiment, the semiconductor component furthermore comprises at least one second functional element which is arranged within the substrate and which is electrically conductively connected to the first functional element via at least one electrically conductive contact layer. Preferably, the second functional element is a CMOS functional element or component. As a result of the global crystallographic (100) orientation of the substrate, the fabrication of such CMOS components, for example in the context of a heterogeneous “on-wafer” integration, is possible simply and well.

Furthermore, a method for producing a semiconductor component in a substrate having a crystallographic (100) orientation, is provided wherein the method comprises the following method steps: masking the regions of the surface of the substrate which lie away from the semiconductor component to be produced. Etching a structure within the unmasked region of the surface of the substrate, which provides at least one structure surface having a crystallographic (111) orientation. Epitaxy of a gallium nitride layer within the etched structure and on the at least one structure surface having the crystallographic (111) orientation. To put it another way, the method according to the invention comprises the step of etching a structure having at least one oblique face—relative to the surface of the substrate—which is crystallographically (111)-oriented. By means of such a method, regions within the surface of a crystallographically (100)-oriented substrate which have crystallographically (111)-oriented crystal planes as surfaces can be produced in a simple manner.

In one preferred further development of the method for producing a semiconductor component in a substrate having a crystallographic (100) orientation, the step of etching involves carrying out anisotropic and/or moist etching. Anisotropic etching methods have developed into a key technology in the semiconductor industry. In anisotropic etching, use is made of the fact that specific etchants remove a silicon single crystal, for example, at different rates along the principal crystal planes, wherein the rate of removal may differ by a number of orders of magnitude depending on the crystal orientation.

Preferably, in the method for producing a semiconductor component in a substrate having a crystallographic (100) orientation, the step of etching involves etching a notch formed by two convergent structure surfaces each having a crystallographic (111) orientation, wherein the depth of the notch is determined by the contact of the structure surfaces with one another. In such an exemplary embodiment, the depth of the structure is set in a self-aligned manner along the height of the semiconductor component.

Furthermore preferably, the method for producing a semiconductor component in a substrate having a crystallographic (100) orientation furthermore comprises the method step of depositing a layer for forming a heterostructure with the gallium nitride layer and/or an electrically conductive contact layer and/or at least one further layer in the structure, wherein the at least one further layer forms a dielectric spacer and/or a gate electrode of the semiconductor component. By means of the implementation of such a method, for example a gallium-nitride-comprising transistor, sensor or alternatively a gallium-nitride-comprising radiofrequency or high-power component or a gallium-nitride-comprising light emitting component can be realized in a simple manner.

Advantageous developments of the invention are specified in the dependent claims and described in the description.

### Drawings

Exemplary embodiments of the invention are explained in greater detail with reference to the drawings and the following description. In the figures:

FIG. 1 shows a first exemplary embodiment of a semiconductor component according to the invention,

FIG. 2 shows a second exemplary embodiment of a semiconductor component according to the invention, and

FIG. 3 shows one exemplary embodiment of a method according to the invention.

### EMBODIMENTS OF THE INVENTION

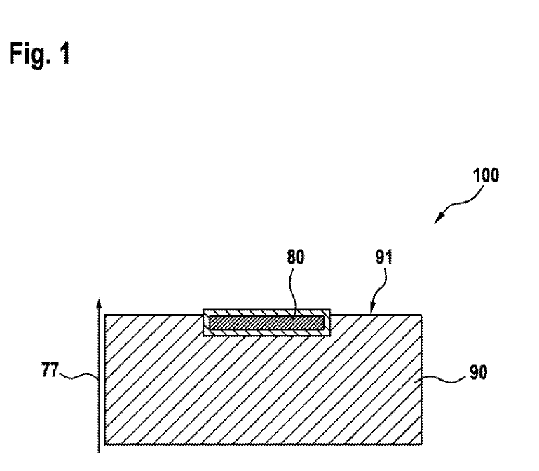

FIG. 1 illustrates a first exemplary embodiment of a semiconductor component 100 according to the invention.

To put it more precisely, a cross section perpendicular to the surface 91 of the semiconductor component 100 is illustrated here in FIG. 1. Said semiconductor component comprises a substrate 90 and a first functional element 80 comprising gallium nitride, said first functional element being realized within the surface 91 of the substrate 90. To put it another way, a first functional element 80 which comprises gallium nitride or at least partly consists of gallium nitride is realized on the surface 91 of the substrate 90 of the semiconductor component 100. The substrate 90 has a crystallographic (100) orientation. To put it another way, the substrate 90 on and/or in whose surface 91 the first functional element 80 is realized has a crystal structure substantially having a crystallographic (100) orientation. To put it yet another way, the substrate relative to the surface 91 of the semiconductor component 100 or the surface 91 of the substrate 90 itself in which the first functional element 80 is realized has a crystallographic (100) orientation. In this first exemplary embodiment, the substrate 90 is purely by way of example the substrate 90 of a silicon wafer substantially having a (100) crystal structure, wherein the triad (100) between parentheses is the Miller indices (hkl) used in crystallography for unambiguously designating crystal faces or planes in a crystal lattice. However, it is also possible to implement semiconductor components 100 according to the invention comprising a substrate 90 which is not the substrate 90 of a silicon wafer.

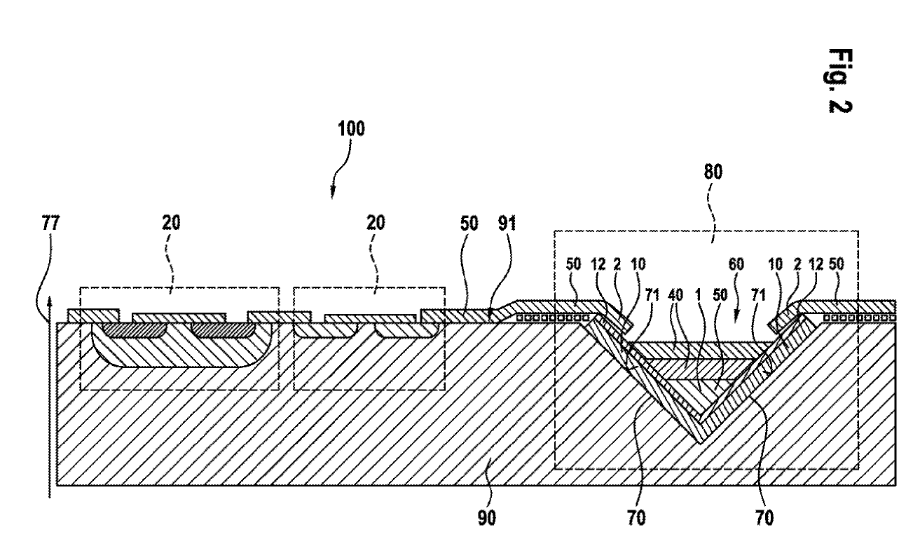

FIG. 2 illustrates a second exemplary embodiment of a semiconductor component 100 according to the invention, which substantially involves the semiconductor component 100 illustrated in FIG. 1. In FIG. 2, too, the semiconductor component 100 is illustrated in a sectional view perpendicular to the surface 91 and along the depth of the semiconductor component 100. The identically designated component parts in FIG. 2 thus correspond to those of the above-described first exemplary embodiment illustrated in FIG. 1. In this second exemplary embodiment, the first functional element 80 comprising gallium nitride is arranged substantially within a structure 70 arranged in the surface 91 of the substrate 90. In this second exemplary embodiment, said structure 70 is purely by way of example a cutout 60 which forms a notch 70 in the surface 91 of the substrate 90 and has two structure surfaces 71 each having a crystallographic (111) orientation. To put it another way, in this second exemplary embodiment, a structure 70 is arranged in the surface 91 of the substrate 90, which structure forms a notch 70 in the surface 91 of the substrate 90 whose structure surfaces 71 are formed by in each case (111)-oriented crystal planes. Within said notch 70 or, to put it more precisely, on the two surfaces which form the notch 70, that is to say which constitute the structure surfaces 71 of the structure 70, a substantial part of the first functional element 80 is realized. These two structure surfaces 71 are in each case substantially crystallographically (111)-oriented relative to the surface 91 of the semiconductor component 100, that is to say angled relative to the crystallographically (100)-oriented surface 91 of the substrate 90. In this second exemplary embodiment, the two common structure surfaces 71 having a V-shaped cross section are thus purely by way of example (111) silicon [1, 2].

However, it is also possible to implement semiconductor components 100 according to the invention which comprise first functional elements 80 on structures 70 whose structure surfaces do not jointly have a V-shaped course in cross section or do not form a notch 70 and which also comprise only one or no crystallographically (111)-oriented structure surface 71 at all or in which only one or no structure surface 71 at all is formed by a (111)-oriented crystal plane.

In this second exemplary embodiment, a gallium nitride layer 10 is in each case grown on the crystallographically (111)-oriented structure surfaces 71, said gallium nitride layer forming a part of the first functional element 80. In other exemplary embodiments, the gallium nitride layers 10 can also be deposited on the crystallographically (111)-oriented structure surfaces 71 in a different way than by means of epitaxy. Furthermore, in this second exemplary embodiment, a layer for forming a heterostructure 12 with the gallium nitride layer 10 is arranged within the structure 70, that is to say within the notch 70. Said layer for forming a heterostructure 12 with the gallium nitride layer 10 can be an aluminum gallium nitride layer, for example, that is to say an AlGaN layer, or alternatively any other layer desired. In this second exemplary embodiment, the surfaces of the gallium nitride layers 10 and also the surfaces of the layers for forming a heterostructure 12 with the gallium nitride layers 10 run in each case parallel to the structure surfaces 71 on which they are deposited. Furthermore, an electrically conductive contact layer 50 is deposited within the structure 70 or within the notch 70, said electrically conductive contact layer being purely by way of example a metallization layer in this second exemplary embodiment. However, the electrically conductive contact layer 50 can also be embodied in a nonmetallic fashion. In this second exemplary embodiment, the surface of said electrically conductive contact layer 50 does not run parallel to the structure surfaces 71, but rather parallel to the surface 91 of the semiconductor component 100, that is to say parallel to the surface 91 of the semiconductor component 100 away from the structure 70. In such a state or with the above-described component parts or layers, the semiconductor component 100 according to the invention can form for example the basis for an electrical diode.

In this second exemplary embodiment, however, two further layers 40 are furthermore arranged in the structure 70 or provided within the notch 70. In this second exemplary embodiment, the two further layers 40 are deposited purely by way of example one above the other within the structure 70 on the electrically conductive contact layer 50. The first of the two further layers 40, which is deposited directly, that is to say immediately, on the electrically conductive contact layer 50, forms a dielectric spacer or a dielectric spacer layer, while the second of the two further layers 40, which is deposited directly, that is to say immediately, on the first further layer 40, that is to say the spacer layer, functions purely by way of example as a gate electrode of the semiconductor component 100 in this second exemplary embodiment. However, it is also possible to implement semiconductor components 100 according to the invention which comprise no further layer, only one further layer or else more than two further layers 40, depending on what kind of semiconductor component 100 is realized or what function is fulfilled by the semiconductor component 100. In this second exemplary embodiment, the dielectric spacer layer electrically isolates the gate electrode of the first functional element 80 from a source electrode 1, which in this second exemplary embodiment is formed purely by way of example by the electrically conductive contact layer 50 below the spacer layer.

Furthermore, the semiconductor component 100 in this second exemplary embodiment comprises purely by way of example two second functional elements 20 arranged within the substrate 90, said second functional elements being electrically conductively connected to the first functional element 80 via at least one electrically conductive contact layer 50. In this second exemplary embodiment, the electrically conductive contact layer 50 purely by way of example is deposited in a structured fashion on the surface 91 of the substrate 90 and respectively on the surface of the first and respectively second functional elements 80, 20 and is led on both sides right into the structure 70 of the first functional element 80. To put it another way, the electrically conductive contact layer 50, which electrically conductively connects the second functional elements 20 to the first functional element 80, is in contact with the layers for forming a heterostructure 12 with the gallium nitride layer 10 of both structure surfaces 71 without contacting the further layer 40 forming the gate electrode. In this second exemplary embodiment, that part of the electrically conductive contact layer 50 which lies within the structure 70 or projects into the structure 70 forms a drain electrode 2 purely by way of example. However, it is also possible to realize other semiconductor components 100 according to the invention which are configured differently or in which the source and drain electrodes 1, 2 are interchanged.

In this second exemplary embodiment, the distance between the source and drain electrodes 1, 2 of the first functional element 80 is defined by the width of the spacer layer within the structure 70. However, it is also possible to realize semiconductor components 100 according to the invention in which no layer, only one layer or more than two further layers 40 are provided which can also perform arbitrary other functions or alternatively constitute arbitrary other component parts of the semiconductor component 100. By way of example, further layers 40 can be deposited which are embodied as chemically sensitive layers or as other functional layers, for example biochemical sensors.

In this second embodiment, the first functional element 80 of the semiconductor component 100 is a transistor purely by way of example. To put it more precisely, the first functional element 80 in this exemplary embodiment is purely by way of example a so-called HEMT, that is to say a high-electron-mobility transistor, that is to say a transistor having high electron mobility. However, it is also possible to implement semiconductor components 100 according to the invention in which the first functional element 80 is embodied as a MOSFET. Furthermore, it is also possible to realize semiconductor components 100 according to the invention in which the first functional element 80 is a sensor, a diode, a radiofrequency or high-power component, a luminous element or alternatively a completely different first functional element 80. Furthermore, a first functional element 80 can also merely provide the basis for, for example, one of the components mentioned above. Generally, a first functional element 80 can be an arbitrary one-terminal component, an arbitrary two-terminal component or alternatively an arbitrary three-terminal component.

In this second exemplary embodiment, the two second functional elements 20 already mentioned are purely by way of example an NMOS transistor and a PMOS transistor arranged alongside one another and alongside the first functional element 80 within the substrate 90. However, it is also possible to implement semiconductor components 100 according to the invention which comprise no, only one or more than two second functional elements 20. These second functional elements 20, too, need not be transistors. The second functional elements 20 of semiconductor components 100 embodied according to the invention can also be other, in particular CMOS, functional elements. Consequently, according to the invention it is possible to provide complex heterogeneous semiconductor components 100 which can be used for example as drivers for light emitting diodes, as signal processors for radiofrequency or high-frequency communication or for any other applications.

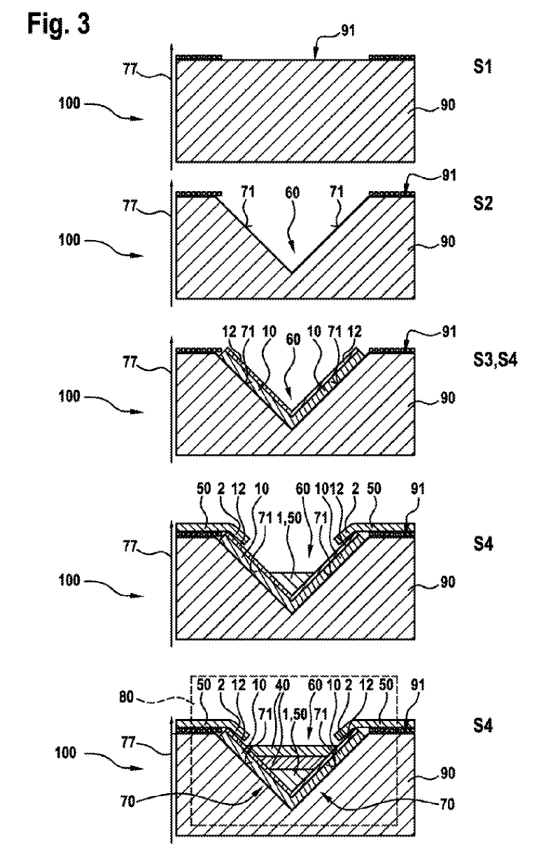

FIG. 3 illustrates one exemplary embodiment of a method according to the invention for producing a semiconductor component 100 in a substrate 90 having a crystallographic (100) orientation. Said method involves firstly providing a substrate 90 having a crystallographic (100) orientation. To put it another way, in the context of the method, a substrate 90 is provided which, relative to the surface 91 thereof in which the semiconductor component 100 is to be produced, has a (100) orientation or which, relative to said surface 91, is constructed from (100)-oriented crystal planes. In the first method step S1, the regions of the surface 91 of the substrate 90 which lie away from the semiconductor component 100 to be produced in the substrate 90 are masked for example with a photoresist or with a photoresist coating. To put it another way, in this exemplary embodiment of the method, the regions of the surface 91 of the substrate 90 which are intended to remain unprocessed are masked in a first method step S1. Afterward, in the second method step S2 of this exemplary embodiment, a structure 70 is etched within the unmasked region of the surface 91 of the substrate 90. In this case, the etching of the structure 70 is performed so as to provide at least one, in this exemplary embodiment of the method purely by way of example two, structure surfaces 71, having in each case a crystallographic (111) orientation, from the structure 70. To put it another way, this exemplary embodiment of the method involves etching a structure 70 with two crystallographically (111)-oriented structure surfaces 71. To put it in yet another way, this exemplary embodiment of the method involves etching a structure whose structure surfaces 71 are formed by two (111)-oriented crystal planes. In the third method step S3, in the context of an epitaxy, a gallium nitride layer 10 is grown within the etched structure 70 on the two structure surfaces 71 having in each case a crystallographic (111) orientation.

In this exemplary embodiment, the method comprises an optional fourth method step S4, in which a layer for forming a heterostructure 12 with the gallium nitride layer 10 is deposited on the gallium nitride layer 10. Afterward, in the fourth method step S4 in this exemplary embodiment, an electrically conductive contact layer 50 and on the latter purely by way of example two further layers 40 are deposited in the structure 70, wherein the first of the deposited further layers 40 is a dielectric spacer layer, while the further layer 40 is a layer of the semiconductor component 100 which forms a gate electrode. In this exemplary embodiment of the method, the electrically conductive contact layer 50, after its deposition, is subjected to thermal aftertreatment purely by way of example. Furthermore, it is possible to implement methods according to the invention in which yet other further layers 40 are deposited within the structure 70, which layers can be for example layers for reducing defects in the layers lying below said further layers 40. Moreover, layers for stress reduction or stress adaptation of the abovementioned or other layers of the semiconductor component 100 can be deposited within the structure 70 in the context of methods implemented according to the invention.

In this exemplary embodiment of the method, moist and anisotropic etching is carried out purely by way of example in the second method step S2. In this exemplary embodiment, the etching is carried out purely by way of example by means of potassium hydroxide, that is to say KOH solution. However, it is also possible to implement methods according to the invention in which etching is carried out using other acids or completely differently, for example as dry etching. Furthermore, in this exemplary embodiment, the second method step S2 of etching involves etching a notched cutout 60 or a notch 70 formed by two convergent structure surfaces 71 having in each case a crystallographic (111) orientation, wherein the depth of the notch 70 is determined by the contact of the structure surfaces 71 with one another. To put it another way, in this exemplary embodiment, the second method step S2 purely by way of example involves etching a notch 70 into the surface 91 of the substrate 90, which notch has two structure surfaces 71 situated in an angled fashion with respect to one another.

FIGS. 1 to 3 illustrate the semiconductor components 100 in each case along an axis 77, wherein the axis 77 runs in each case parallel to the height of the semiconductor component 100.

1. A semiconductor component, comprising:
a substrate having a crystallographic (100) orientation; and
a first functional element including gallium nitride, said first functional element realized within a surface of the substrate.

2. The semiconductor component as claimed in claim 1, wherein the substrate is a silicon substrate.

3. The semiconductor component as claimed in claim 1, wherein the first functional element including gallium nitride is arranged at least partly within a structure arranged in the surface of the substrate.

4. The semiconductor component as claimed in claim 3, wherein:
the structure is a cutout forming a notch in the surface of the substrate, and
at least one surface of the structure has a crystallographic (111) orientation.

5. The semiconductor component as claimed in claim 4, wherein the structure has a V-shaped cross section and two surfaces of the structure are angled with respect to one another and with respect to the surface of the substrate, which have in each case a crystallographic (111) orientation.

6. The semiconductor component as claimed in claim 4, wherein at least one gallium nitride layer which forms a part of the first functional element is grown on the at least one surface of the structure.

7. The semiconductor component as claimed in claim 6, wherein:
at least one of a layer for forming a heterostructure with the at least one gallium nitride layer, an electrically conductive contact layer, and at least one further layer is arranged within the structure, and
the at least one further layer forms at least one of a dielectric spacer and a gate electrode of the semiconductor component.

8. The semiconductor component as claimed in claim 1, further comprising:
at least one second functional element arranged within the substrate and electrically conductively connected to the first functional element via at least one electrically conductive contact layer.

9. A method for producing a semiconductor component in a substrate having a crystallographic (100) orientation, comprising:
masking regions of a surface of the substrate which lie away from the semiconductor component;
etching a structure within the unmasked region of the surface of the substrate the structure including at least one surface having a crystallographic (111) orientation; and
epitaxing a gallium nitride layer within the etched structure and on the at least one surface having the crystallographic (111) orientation.

10. The method of claim 9, wherein the etching comprises:
carrying out at least one of anisotropic and moist etching.

11. The method of claim 9, wherein the etching comprises:
etching a notch formed by two convergent surfaces of the structure each having a crystallographic (111) orientation; and
determining a depth of the notch by contact of the two convergent surfaces with one another.

12. The method of claim 9, further comprising:
depositing a layer for forming a heterostructure with the gallium nitride layer and/or an electrically conductive contact layer and/or at least one further layer in the structure; and
forming at least one of a dielectric spacer and a gate electrode of the semiconductor component with the at least one further layer.
